(19) United States
(12) Patent Application Publication
(10) Pub. No.: US 2004/0061152 A1
(43) Pub. Date: Apr. 1, 2004

(54) Semiconductor photosensor device

(75) Inventors: Yukiko Kashiura, Yokohama-shi (JP); Hiroshi Suzunaga, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/294,721

(22) Filed: Nov. 15, 2002

(30) Foreign Application Priority Data
Sep. 26, 2002 (JP) 2002-281609

(51) Int. Cl. H01L 31/062

(52) U.S. Cl. 257/292

(57) ABSTRACT

A semiconductor photosensor device has a semiconductor substrate, a semiconductor layer overlying the semiconductor substrate while being separated therefrom by a dielectric film, a first photodiode formed in the semiconductor layer to be disposed adjacent to a top surface of the semiconductor layer, a second photodiode formed in the semiconductor layer to be underlain the first photodiode, and a signal processing circuit formed on said semiconductor layer for processing output signals of said first and second photodiodes.

### CROSS-REFERENCE TO RELATED APPLICATION

This application is based upon and claims the benefit of priority from the prior Japanese Patent Application No. 2002-281609, filed on Sep. 26, 2002, the entire content of which is incorporated herein by reference.

### BACKGROUND OF THE INVENTION

1. Field of the Invention

This invention relates to a semiconductor photosensor device.

2. Description of Related Art

In currently available semiconductor photosensor devices, there are called illuminance sensors which have spectral sensitivity characteristics similar to the luminosity characteristics of human eyes. Semiconductor illuminance sensors are typically utilizable for light intensity control and adjustment of display modules for use in portable or “mobile” wireless telephone handsets, by way of example. As shown in FIG. 4, a luminosity characteristics curve has a sharp hump or “peak” between wavelength values of 500 and 600 nanometers (nm). On the other hand, a spectral sensitivity characteristics curve of silicon photodiodes has a peak sensitivity at a point near or around 960 to 980 nm as shown in FIG. 5. Accordingly, in order to realize an illuminance sensor by use of a silicon substrate, a method is used which forms on or above a photodiode an optical filter that absorbs infrared light components while permitting penetration of visible light components. Examples of the optical filter are dielectric multilayer-film interference filters and color filters.

It is also possible to achieve desired spectral sensitivity characteristics without the use of the optical filter. Silicon substrates are such that short wavelength light components are mainly absorbed at portions adjacent to a surface whereas long wavelength light components are mainly absorbed at portions deep from the surface. Utilizing such silicon light absorption properties, it is possible to obtain a desired spectral sensitivity by arithmetic processing for output currents from two photodiodes that are vertically laminated in a silicon substrate. Techniques for forming on a semiconductor substrate a plurality of photodiodes which are separated or isolated from one another while having different depths have been proposed until today. One of the techniques is disclosed, for example, in Published Unexamined Japanese Patent Application No. 11-163386 (“JP-A-11-163386”).

In such a case that photodiodes with mutually different spectral sensitivity characteristics are formed in a single semiconductor substrate at different depth positions thereof, the influence of noise light input into the substrate pauses problems through the procedure of arithmetic processing of these photocurrents. In detail, when the sensor chip is irradiated, light rays are input not only onto the photo detective surface, but also onto side surfaces of the substrate. Due to extra carriers that are generated by the noise light into unexpected portions of the substrate, it becomes difficult to obtain a desired spectral sensitivity by photocurrent arithmetic. In such a case that a signal processing circuit for performing arithmetic processing for photocurrents is formed in the same semiconductor substrate together with the photodiodes, the influence of the noise light into the processing circuit region also becomes problematic.

Practically in the sensor chip of this type, it is required that the incoming light be guided to fall onto only specific areas in which the photodiodes are formed. To do this, the remaining areas are covered or coated with a light shielding mask. However, it is difficult to cover certain portions with the light shield mask, which portions include the chip's outermost peripheral portions at which scribe lines are formed and side surfaces. The result of this mask coverage incompletion is that light invasion from these portions into the silicon substrate is unavoidable. In particular, from the chip side faces, an increased amount of light which was reflected from a chip-mounting base structure will also encroach. Accordingly, extra carrier currents due to the noise light rays are generated and superimposed to the true photocurrents of the photodiodes, whereby it becomes difficult to precisely process the photocurrent arithmetic.

Practically, in the case of an illuminance sensor, the above-stated invasion of noise light rays into the substrate disadvantageously results in a significant difference between outputs of the sensor when illuminated at the same illumination intensity by a fluorescent lamp which emits light that does not contain any infrared light components and a white electric lamp whose emission light includes many infrared light components because the infrared light components deeply penetrate into the substrate to affect the photocurrent arithmetic and a signal processing circuit.

### SUMMARY OF THE INVENTION

A semiconductor photosensor device is provided to include a semiconductor substrate, a semiconductor layer overlying the semiconductor substrate while being separated therefrom by a dielectric film, a first photodiode formed in the semiconductor layer to be disposed adjacent to a top surface of the semiconductor layer, a second photodiode formed in the semiconductor layer to be underlain the first photodiode, and a signal processing circuit formed on the semiconductor layer for processing output signals of the first and second photodiodes.

### BRIEF DESCRIPTION OF THE DRAWINGS

FIG. 1 is a cross-sectional diagram of main part of a photosensor chip in accordance with an embodiment of this invention.

FIG. 2 is a diagram showing a plan view of the photosensor.

FIG. 3 is a diagram showing a configuration of a current arithmetic circuit which is mounted on the photosensor chip.

FIG. 4 is a graph showing a luminosity characteristics curve as plotted relative to the wavelength of incident light.

FIG. 5 is a graph showing the spectroscopic sensitivity characteristics curve of a silicon photodiode.

FIG. 6 is a graph showing the spectroscopic sensitivity characteristics of two photodiodes in accordance with an embodiment of this invention.

FIG. 7 is a diagram showing in cross-section main part of a photosensor chip in accordance with another embodiment of the invention.

### DETAILED DESCRIPTION OF THE INVENTION

A photosensor device in accordance with an embodiment of this invention will be explained with reference to the accompanying figures of the drawing below.

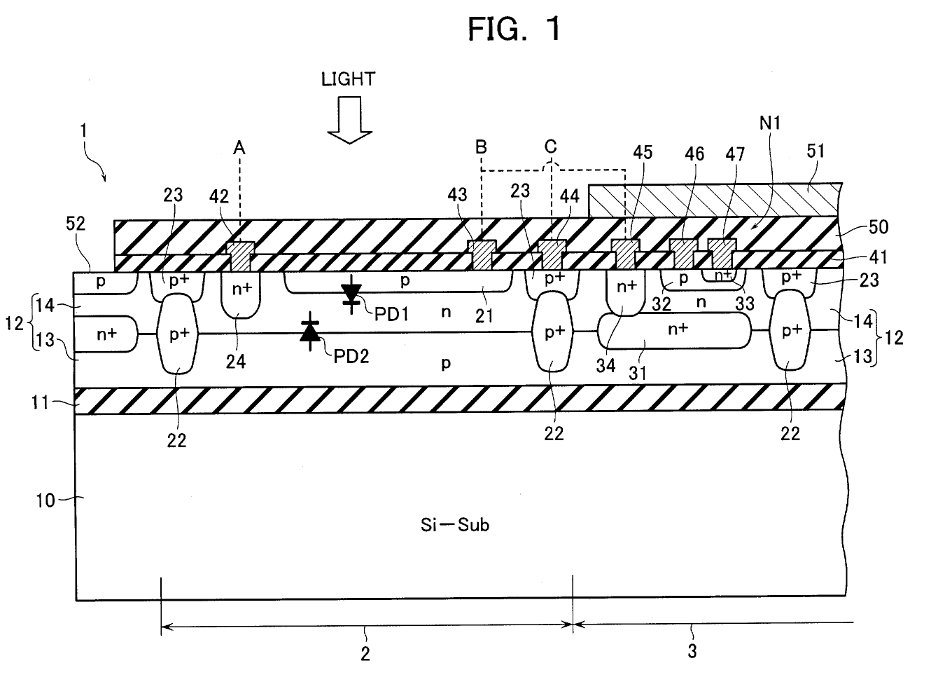

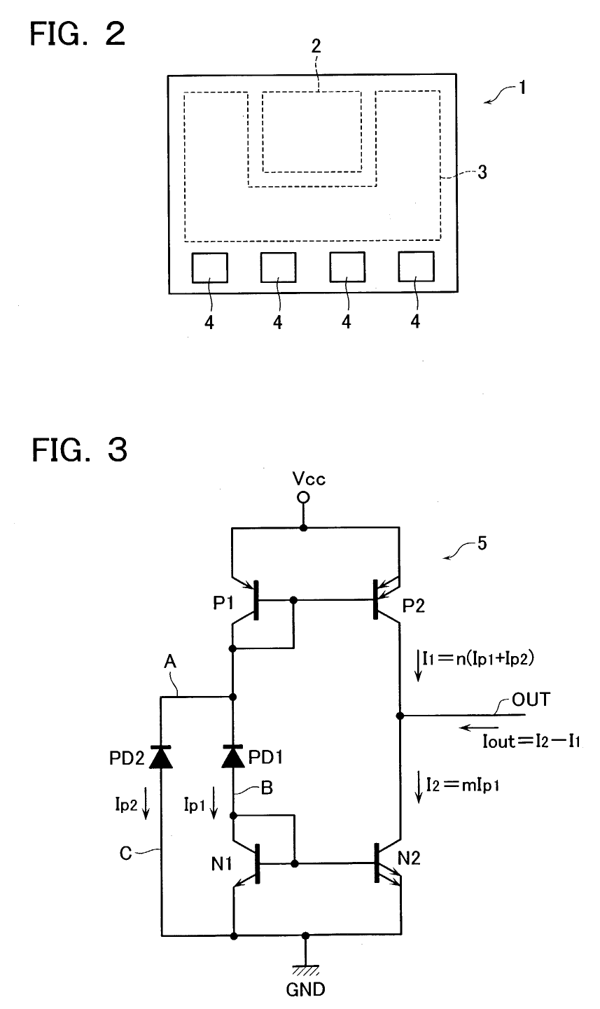

FIG. 1 illustrates, in cross-section, a structure of main part of an illuminance sensor chip 1 embodying the invention; FIG. 2 schematically shows a planar layout of the sensor chip 1. As indicated by broken lines in FIG. 2, the sensor chip 1 has a photodiode module (optical receiving unit or light receiver unit) 2 and a signal processing circuit module 3 operable to arithmetically process an output photocurrent of the photodiode unit. The signal processing circuit unit 3 is covered with a light shield mask. External connection pads 4 are disposed along a peripheral side of the chip 1.

As shown in FIG. 1, the sensor chip 1 employs a silicon-on-insulator (SOI) substrate structure which includes a silicon substrate 10 and an overlying silicon layer 12 with a dielectric film 11 interposed therebetween. The silicon layer 12 is electrically separated or isolated from substrate 10 by dielectric film 11. This film 11 may typically be an oxide film or the like. Silicon layer 12 essentially consists of a P-type layer 13 in contact with dielectric film 11 and an N-type epitaxial layer 14 that is formed on the P-type layer 13. Preferably, P-type layer 13 is higher in impurity concentration than N-type layer 14 and is designed to have a thickness less than or equal to 15 micrometers (μm).

At the photodiode unit 2 of this SOI substrate, two separate photodiodes PD1, PD2 are formed so that these vertically overlap each other. One photodiode PD1 uses as its optical receiving junction a PN junction between the N-type layer 14 and a P-type layer 21 which is formed by diffusion in a surface portion of layer 14. The other photodiode PD2 is with a PN junction between the P-type layer 13 and N-type layer 14 as its light-receiving junction. In this way, the photodiode PD1 having its light receiving junction near the top surface of the layer 12 and the photodiode PD2 underlying the photodiode PD1 as to have its light receiving junction at a level deeper than photodiode PD1 are formed in the silicon layer 12 while using N-type layer 14 as a common cathode layer thereof. The impurity concentration and the depth of the N-type common cathode layer 14 are selected such that the layer 14 is not completely depleted when a necessary reverse bias voltage is applied to the photodiodes PD1 and PD2. As a result, depletion layers formed above and bellow the layer 14 that remains to be not depleted become light absorption layers of the photodiodes PD1-PD2, respectively. The photodiode unit 2 is surrounded or enclosed by a P⁺-type buried layer 22 and a P⁺-type diffusion layer 23 and thus isolated from the remaining regions of the sensor chip substrate structure.

A transistor circuit is formed in the signal processing circuit unit 3. In FIG. 1, only part of the signal processor circuit is shown, which is an NPN transistor N1 as used in a current arithmetic circuit that is included in the signal processor circuit and is operable to perform arithmetic processing of photocurrents of two photodiodes PD1, PD2. The transistor N1 is structured with the N-type layer 14 as its collector and with a P-type base layer 32 and an N⁺-type emitter layer 33 being formed therein. An N⁺-type collector buried layer 31 is formed at a junction between the N-type layer 14 and its underlying P-type layer 13.

The illustrative sensor chip substrate with the electronic components or elements formed therein is covered with a silicon oxide film 41. Contact holes are defined in this oxide film 41 to thereby form several terminal electrodes required. An electrode 42 for use as a common cathode node “A” of the photodiodes PD1-PD2 is in contact with an N⁺-type diffusion layer 24 which is formed in the N-type layer 14. Electrodes 43, 44 for use as anode nodes B, C of photodiodes PD1-2 are contacted with the P-type layer 21 and P⁺-type layer 23, respectively. A collector electrode 45, a base electrode 46 and an emitter electrode 47 are formed simultaneously during the formation of these photodiode electrodes.

The top substrate surface in which each terminal electrode is formed is further covered with a silicon oxide film 50, followed by formation of a light shield mask 51 which covers the signal processor circuit unit 3. For example, the light shield mask 51 is formed by using the same metal film as that of a metal wiring lead (not shown) for use as an extension of each terminal electrode.

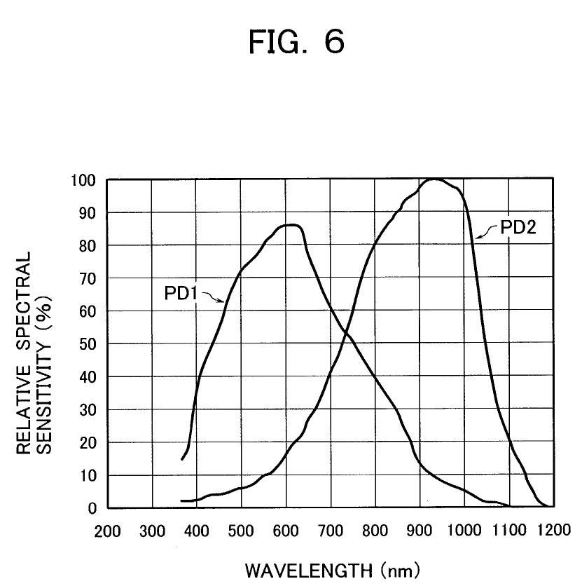

The illuminance sensor chip 1 is such that incident light incomes from upper part of it and then passes through the oxide films 50, 41 to fall onto the photodiode unit 2. The photodiode PD1, which has a shallow light receiving junction, functions to mainly absorb short wavelength light components of the incoming light. The photodiode PD2 having a deeper light-receiving junction than that of photodiode PD1 mainly absorbs longer wavelength light components. Thus, these photodiodes PD1-PD2 exhibit their own spectral sensitivity characteristics such as indicated by curves plotted in a graph of FIG. 6. In view of the photodiode properties, performing arithmetic processing of the output photocurrents of photodiodes PD1-PD2 makes it possible to obtain a sensor output having a desired spectral sensitivity. In order to detect or sense only visible rays of the incoming light, let the photocurrents, Ip1 and Ip2, of photodiodes PD1-2 be subjected to such an arithmetic operation as to subtract a predetermined multiple of Ip2 from Ip1.

FIG. 3 shows a configuration of the current arithmetic circuit 5 as used in the signal processor circuit unit 3 of this embodiment. This circuit includes a pair of PNP transistors P1, P2, which make up a current mirror for detection of a total photocurrent of the two photodiodes PD1-PD2. The transistor P1 has its base and collector which are connected together to a common cathode node A of photodiodes PD1-2 and also has an emitter connected to a power supply voltage node Vcc. The PNP transistor P2 is for use as an output-stage transistor and has its base connected to the base of transistor P1, an emitter connected to the supply voltage node Vcc, and a collector coupled to an output node OUT of the current arithmetic circuit 5.

The arithmetic circuit 5 of FIG. 3 further includes a pair of NPN transistors N1, N2 which make up a current mirror for detection of a photocurrent of the photodiode PD1, although only one of them—the transistor N1—is shown in FIG. 1. Transistor N1 has its base and collector connected to the anode node B of photodiode PD1 and an emitter coupled to a ground node GND. Transistor N2 acts as an output-stage transistor. This output NPN transistor N2 has a base connected to the base of transistor N1, an emitter connected to ground node GND, and a collector connected to output node OUT. The anode node C of photodiode PD2 is coupled to ground GND.

In the FIG. 3 circuit, an emitter area ratio of the transistors P1-P2 and an emitter area ratio of the transistors N1-N2 are set at optimal values to ensure that an output of desired spectral sensitivity is obtained in accordance with the respective spectral sensitivity characteristics of two photodiodes PD1-PD2. For instance, suppose that the emitter area of transistor P2 is set at a value which is n times (where “n” is a given positive number) greater than that of transistor P1 while setting the emitter area of transistor N2 at a value m times (“m” is a positive number) greater than that of transistor N1.

When incident light falls onto the light receiving unit 2 of photosensor chip 1, an output current Iout of the current arithmetic circuit 5 becomes substantially equal to Iout=I2−I1, where I1 is a collector current of the transistor P2, and I2 is a collector current of transistor N2. The collector current I1 of transistor P2 is represented by I1=n(Ip1+Ip2), where Ip1 and Ip2 are the photocurrents of two photodiodes PD1-PD2. The collector current I2 of transistor N2 is given as I2=m·Ip1. Thus, the output current Iout is represented by Equation 1, which follows.

$$\begin{matrix}Iout = m \cdot Ip1 - n ( Ip1 + Ip2 ) \\ = ( m - n ) [ Ip1 - \{ n / ( m - n ) \} Ip2 ]\end{matrix} \qquad ( 1 )$$

From Equation 1, it is seen that the output current Iout has a value obtained by the operation of deducting from the photocurrent Ip1 of the photodiode PD1 with significant sensitivity in a short wavelength range a number which is n/(m−n) times of the photocurrent Ip2 of photodiode PD2 with significant sensitivity in a long wavelength range. In other words, the output current Iout is equal to Ip1 subtracted by a product resulting from the multiplication of Ip2 and n/(m−n). For example, in such a case that the spectral sensitivity characteristics of photodiodes PD1-PD2 are as shown in FIG. 6, a magnification (emitter area ratio) of the current mirror of the transistors P1-P2 is set at n=1 whereas a magnification (emitter area ratio) of the current mirror of the transistors N1-N2 is m=4. With this value setup, the output current Iout is given by Equation 2 which follows.

Iout=Ip1−0.333×Ip2 (2)

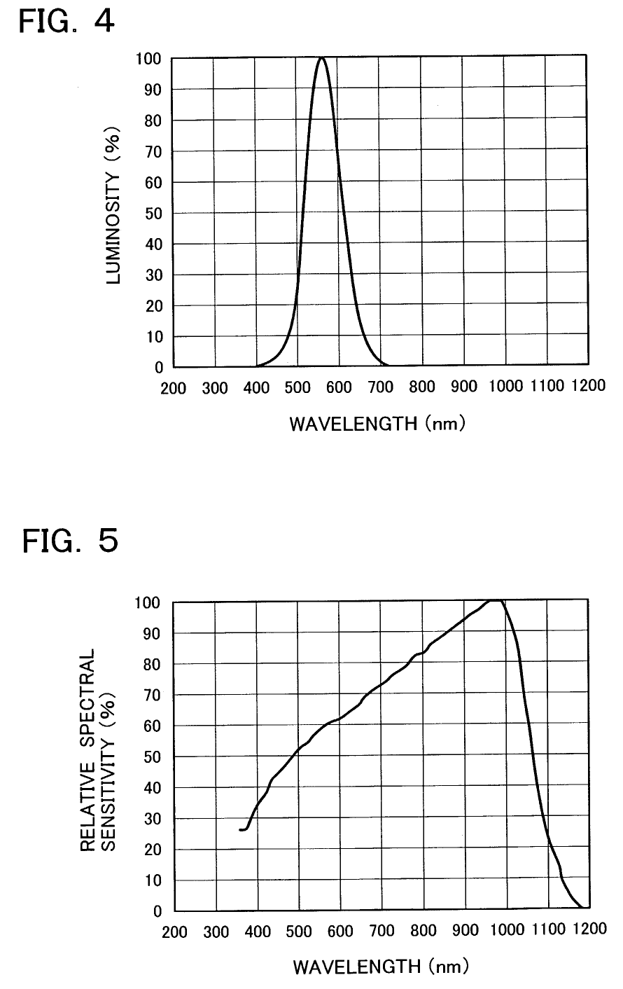

Under this condition, an output of long wavelength light components of the photodiode PD1 and an output of photodiode PD2 cancel each other out. Thus it is expected that spectral sensitivity characteristics corresponding to the luminosity characteristics shown in FIG. 4 and having no sensitivities in wavelength regions of more than 800 nm be obtained.

In this embodiment, as described above, photodiodes PD1, PD2 are isolated from the silicon substrate 10 by the dielectric film 11. Therefore, even if carriers are generated in the substrate 10 in response to the noise light rays input into the substrate 10, the dielectric film 11 prevents the carriers from diffusing into the P-layer 13. In other words, the carriers generated in the substrate 10 by the noise light rays are not superimposed to the photocurrents of photodiodes PD1, PD2, whereby it is possible to obtain a desired spectral sensitivity. Similarly, the carriers generated in the substrate 10 due to noise light rays input into the substrate 10 do not affect signal processing circuit 3.

As previously stated, in this embodiment, two photodiodes PD1-PD2 having light receiving junctions of different depths are formed at the “common” photodiode unit (optical receiving unit) 2 of the silicon layer 12 of the SOI substrate structure in such a manner that these photodiodes are vertically laminated or stacked over each other. Accordingly, the two photodiodes PD1-2 are formed to have a common small-size light-receiving surface, unlike the case of forming them at different positions within the substrate surface. Moreover, the resultant sensor chip becomes simplified both in structure and in fabrication process, when compared to the prior art with two photodiodes formed at different positions of a substrate while having thickness-different light absorption layers.

As apparent from the foregoing, the illuminance sensor is obtained which is capable of correctly detecting the intensity of illuminance even under any environments irrespective of the use of either fluorescent lamps or white electric lamps. Especially, it has been affirmed through experimentation by the inventors as named herein that setting the thickness of P-type layer 13 at 15 μm or less enables a difference between an output current in the case of irradiation using fluorescent lamps and an output current in the case of radiation of white electric lamps to become sufficiently small and thus almost negligible during the practical use of the signal processor-embedded illuminance sensor incorporating the principles of the invention.

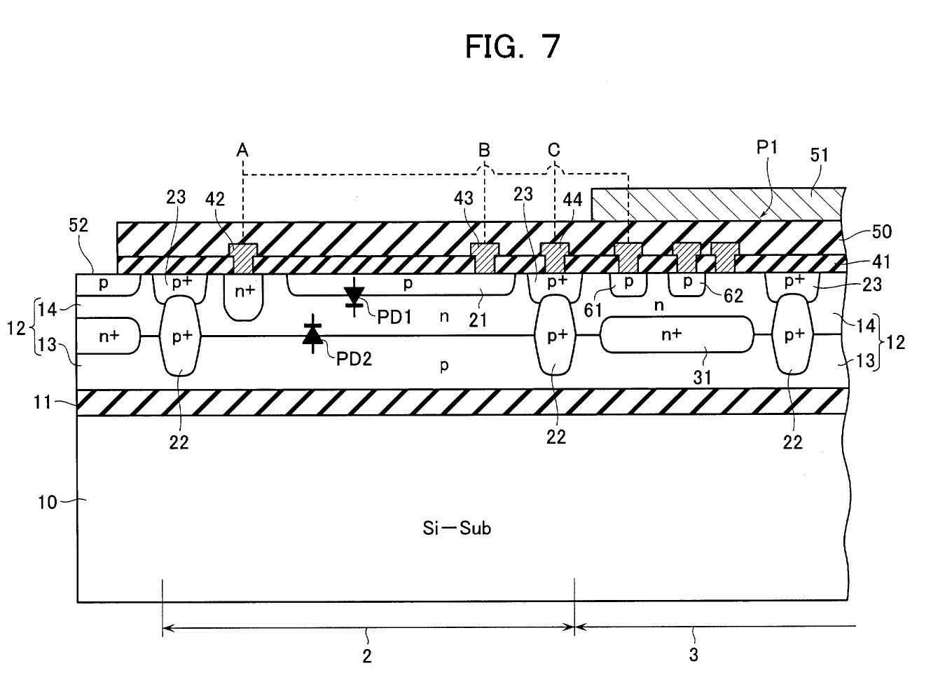

Although in the embodiment device structure of FIG. 1 vertical transistors are used as the transistors of the signal processor circuit 3, lateral transistors may be used as shown in FIG. 7. FIG. 7 shows only one PNP transistor P1 connected to node A, which is an element of the current arithmetic circuit 5. PNP transistor P1 is formed in the N-type layer 14 along with a P⁺-type collector layer 61 and a P⁺-type emitter layer 62 which are formed in this N-type base layer 14.

In standard vertical transistors, a base layer is formed at the surface of a collector layer; thus, extra carrier absorption at the collector layer, which is greater in volume than the base layer, becomes to be problematic. On the contrary, with lateral transistors, the collector and emitter are formed in the base layer so that when a base current flows due to the extra carrier absorption at the base layer; this base current is increased by a factor of h_{FE} to become a collector current. Thus, lateral transistors are inherently greater in the influence of noise light than vertical transistors. Accordingly, in the case of using lateral transistors in signal processing circuitry, a technique for reducing the noise light influence becomes particularly important.

The signal processing circuit 3 includes other circuits subsequently connected to the current arithmetic circuit 5, in which resisters and capacitors may be used in addition to transistors.

It has been stated that according to this invention, it is possible to provide a high-performance semiconductor photosensor device capable of reducing or minimizing the noise light influenceability.

What is claimed is:

1. A semiconductor photosensor device comprising:
a semiconductor substrate;
a semiconductor layer overlying said semiconductor substrate while being separated therefrom by a dielectric film;
a first photodiode formed in said semiconductor layer to be disposed adjacent to a top surface of said semiconductor layer;
a second photodiode formed in said semiconductor layer to be underlain said first photodiode; and
a signal processing circuit formed on said semiconductor layer for processing output signals of said first and second photodiodes.

2. The photosensor device according to claim 1, wherein said semiconductor layer has a first P-type layer in contact with said dielectric film and an N-type layer overlying said first P-type layer, wherein said first photodiode uses a PN junction between said N-type layer and a second P-type layer formed by diffusion at a surface thereof, and wherein said second photodiode uses a PN junction between said first P-type layer and said N-type layer.

3. The photosensor device according to claim 1, wherein said signal processing circuit comprises a current arithmetic circuit for subtracting a current multiplied prespecified value by an output current of said second photodiode from an output current of said first photodiode.

4. The photosensor device according to claim 3, wherein said current arithmetic circuit comprises:
a first PNP transistor with its collector and base connected together to a common cathode of said first and second photodiodes in which an anode of said second photodiode is connected to a ground node and with an emitter connected to a power supply node;
a first NPN transistor with its collector and base connected to an anode of said first photodiode and with an emitter connected to said ground node;
a second PNP transistor constituting a current mirror together with said first PNP transistor and having a collector connected to an output node; and
a second NPN transistor constituting a current mirror together with said first NPN transistor and having a collector connected to said output node.

5. The photosensor device according to claim 4, wherein an emitter area ratio of said first and second PNP transistors and an emitter area ratio of said first and second NPN transistors are set to permit an output current obtained at said output node to have sensitivity only in a specific wavelength region.

6. The photosensor device according to claim 5, wherein an emitter area ratio of said first and second PNP transistors and an emitter area ratio of said first and second NPN transistors are set to permit an output current obtained at said output node to have sensitivity only in a visible light wavelength region.
